(19) United States
(12) Patent Application Publication
(10) Pub. No.: US 2026/0047113 A1
(43) Pub. Date: Feb. 12, 2026

(54) SEMICONDUCTOR STRUCTURE, SEMICONDUCTOR DEVICE, AND METHOD OF MANUFACTURING SEMICONDUCTOR STRUCTURE

(71) Applicant: TAIWAN SEMICONDUCTOR MANUFACTURING COMPANY LTD., HSINCHU (TW)

(72) Inventors: WEI-JEN CHANG, MIAOLI COUNTY (TW); YI-TING CHIANG, TAOYUAN CITY (TW); YU-CHIEN LAI, HSINCHU COUNTY (TW); RUEI-JYUN HSU, HSINCHU CITY (TW); CHIA-CHI HO, HSINCHU COUNTY (TW); CHUNG-SHIH CHIANG, HSINCHU COUNTY (TW)

(21) Appl. No.: 18/796,345

(22) Filed: Aug. 7, 2024

(51) Int. Cl. H01L 29/8605; H01L 29/66

(52) U.S. Cl. CPC H10D 1/43; H10D 1/025

(57) ABSTRACT

A semiconductor structure and a method of manufacturing the semiconductor structure are provided. The semiconductor structure includes a first semiconductor layer, a second semiconductor layer, and a metal layer. The first semiconductor layer including a first material having a first bandgap. The second semiconductor layer is disposed on the first semiconductor layer, wherein the second semiconductor layer includes a second material having a second bandgap, and the second bandgap is different from the first bandgap. The metal layer overlaps the second semiconductor layer. An interface lattice mismatch (carrier channel) is formed between the first semiconductor layer and the second semiconductor layer.

### BACKGROUND

Semiconductor resistors are commonly utilized in integrated circuits to perform various functions and enhance performance of the integrated circuit. During a design stage of the integrated circuit, one of many parameters that are applied to the resistor is temperature coefficient of resistance (TCR), which characterizes a change in resistance per unit change in temperature. The temperature coefficient of resistance remains a critical concern in many applications. Both a negative temperature coefficient of resistance (n-TCR) and a positive temperature coefficient of resistance (p-TCR) are applied in a wide range of components integrated in electronic products. However, there are challenges associated with integrating the components having both n-TCR and p-TCR in a same fabrication line and on a same wafer.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic top view of a portion of a semiconductor device illustrating some embodiments of the present disclosure that include a resistive element having a meandering serpentine-like pattern disposed between two other electronic components of the semiconductor device.

FIG. 2 is a schematic cross-sectional view taken along a line A-A′ in FIG. 1.

FIG. 3 is a perspective view of a portion of a semiconductor device in FIG. 1.

FIG. 4 is a schematic perspective view of a stacked structure that includes a substrate, a first semiconductor layer, a second semiconductor layer, and an isolation feature, in accordance with some embodiments of the present disclosure.

FIG. 5 is a schematic perspective view of a resistive element, in accordance with some embodiments of the present disclosure.

FIG. 6 is a schematic perspective view of a resistive element, in accordance with some embodiments of the present disclosure.

FIG. 7 is a schematic perspective view of a resistive element, in accordance with some embodiments of the present disclosure.

FIG. 8 is a schematic perspective view of a resistive element, in accordance with some embodiments of the present disclosure.

FIG. 9 is a schematic cross-sectional view of a resistive element, in accordance with some embodiments of the present disclosure.

FIG. 10 is a schematic cross-section view of a resistive element, in accordance with some embodiments of the present disclosure.

FIG. 11 is a schematic cross-section view of a resistive element, in accordance with some embodiments of the present disclosure.

FIG. 12 is a flowchart of a method of manufacturing a resistive element, in accordance with some embodiments of the present disclosure.

FIGS. 13 to 17 are cross-sectional views of intermediate stages of the method of manufacturing a resistive element, in accordance with some embodiments of the present disclosure.

FIG. 18 is a flowchart of a method of manufacturing a resistive element, in accordance with some embodiments of the present disclosure.

FIGS. 19 to 23 are cross-sectional views of intermediate stages of the method of manufacturing a resistive element, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for a purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A group III-V electronic device utilizes a junction between two materials with different bandgaps or different lattice constants as a carrier channel. For example, by combining materials with different bandgaps (such as AlGaN and GaN), a quantum well may be formed at the interface between the combined materials. Due to a bandgap discontinuity between two different materials, a two-dimensional electron gas (2DEG) is formed. The 2DEG is also referred to as the carrier channel.

The 2DEG acts as the carrier channel for providing conductivity between electrodes. AlGaN and GaN have lattice structures that differ significantly enough to generate strain at an interface therebetween. The strain-induced piezoelectric polarization and the spontaneous polarization of AlGaN results in electrons being dragged to the quantum well, and thus create a thin layer of highly mobile conducting electrons in the carrier channel. The 2DEG may have a high electron mobility (e.g., 1300 cmV⁻¹S⁻¹) and a high carrier density (e.g., 1˜2E1013). With such high carrier density and mobility, high power at high frequency could be obtainable.

A metal layer is stacked on the AlGaN/GaN electronic device for controlling a temperature-dependent characteristic thereof. For example, the metal layer may be used for tuning a temperature coefficient of resistance of the group III-V electronic device, so that the group III-V electronic device including 2DEG can have a wide range of applications in the electronics field.

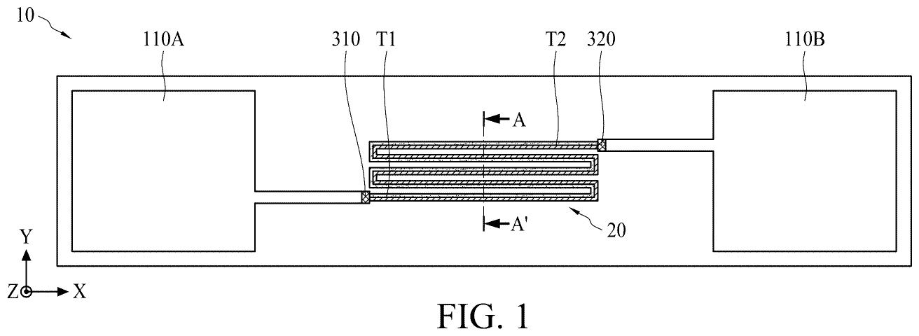

FIG. 1 is a schematic top view of a portion of a semiconductor device 10, in accordance with some embodiments of the present disclosure. Referring to FIG. 1, the semiconductor device 10 includes a resistive element 20 and various electronic components, such as a first electronic component 110A and a second electronic component 110B. In some embodiments, the resistive element 20 is disposed between the first component 110A and the second component 110B. The resistive element 20 may be, for example, a two-dimensional (2D) electron gas resistor. The first and second electronic components 110A and 110B include active components (e.g., transistors, diodes, or the like) and/or passive components (e.g., capacitors, inductors, resistors, etc.).

Referring again to FIG. 1, the resistive element 20 has a first terminal T1 and a second terminal T2. In some embodiments, the resistive element 20 begins at the first terminal T1 and ends at the second terminal T2. The resistive element 20 may be coupled to a first contact pad 310 and a second contact pad 320. For example, the first terminal T1 of the resistive element 20 is connected to the first contact pad 310 that provides an electrical connection to the first electronic component 110A, and the second terminal T2 of the resistive element 20 is connected to the second contact pad 320 that provides an electrical connection to the second electronic component 110B. In some embodiments, the first contact pad 310 and the second contact pad 320 are on opposite sides of the resistive element 20, and the first contact pad 310 is offset from the second contact pad 320 in the Y-direction. In alternative embodiments, the first contact pad 310 and the second contact pad 320 are positioned on a same side or adjacent sides of the resistive element 20. In other alternative embodiments, the first contact pad 310 and the second contact pad 320 are on the opposite sides of the resistive element 20, and the first contact pad 310 is aligned with the second contact pad 320 in the Y-direction.

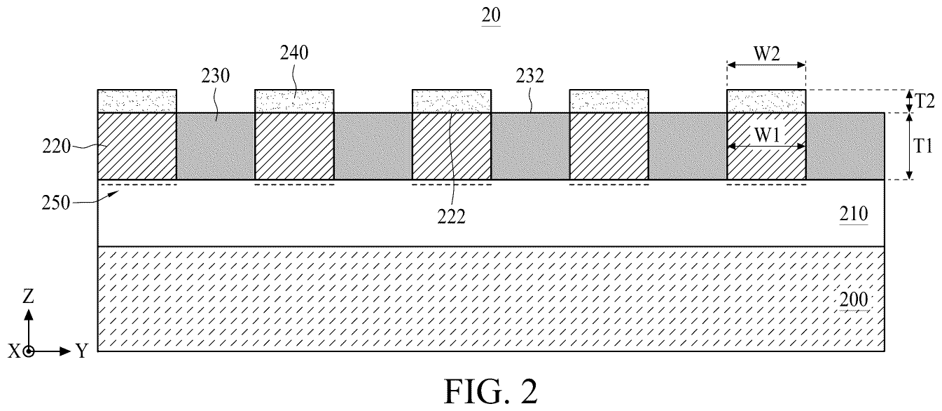

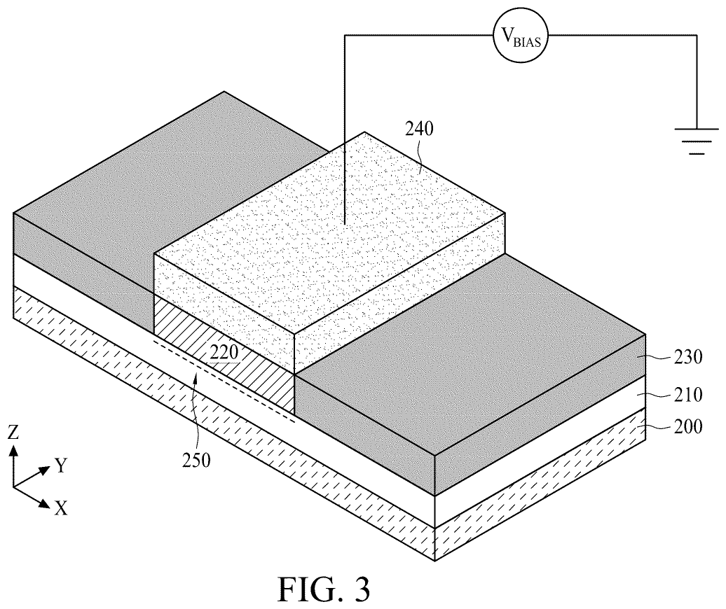

FIG. 2 is a schematic cross-sectional view along a line A-A′ of the semiconductor device 10 in FIG. 1, and FIG. 3 is a perspective view of a portion of the semiconductor device 10 in FIG. 1. Referring to FIGS. 2 and 3, in some embodiments, the resistive element 20 is a group III-V element including a heterojunction structure formed on a substrate 200. The resistive element 20 includes a first semiconductor layer 210, a second semiconductor layer 220, an isolation feature 230, and a metal layer 240. The second semiconductor layer 220 is disposed on the first semiconductor layer 210. In some embodiments, the second semiconductor layer 220 has a meandering serpentine-like pattern from a top-view perspective. The second semiconductor layer 220 may have an asymmetrical serpentine pattern from a top-view perspective (as shown in FIG. 1).

The isolation feature 230 may be disposed on the first semiconductor layer 210 to laterally surround the second semiconductor layer 220. In some embodiments, the isolation feature 230 has an upper surface 232 flush with an upper surface 222 of the second semiconductor layer 220. The isolation feature 230 may be an amorphous III-V compound layer or a dielectric layer. The dielectric layer may include material such as oxide, nitride, other dielectric material, and/or combination thereof.

The metal layer 240 is disposed on the second semiconductor layer 220, and the metal layer 240 may fully overlap the second semiconductor layer 220. In some embodiments, the metal layer 240 has a width W2 that is equal to or greater than a width W1 of the second semiconductor layer 220, so that the metal layer 240 has a pattern that is similar to or substantially same as a pattern of the second semiconductor layer 220 from the top-view perspective. In some embodiments, the second semiconductor layer 220 is entirely overlapped by the metal layer 240. The metal layer 240 may have a thickness T2 that is less than a thickness T1 of the second semiconductor layer 220 or the isolation feature 230. In some embodiments, the thickness T2 is between about 10 angstroms (Å) and about 12000 Å.

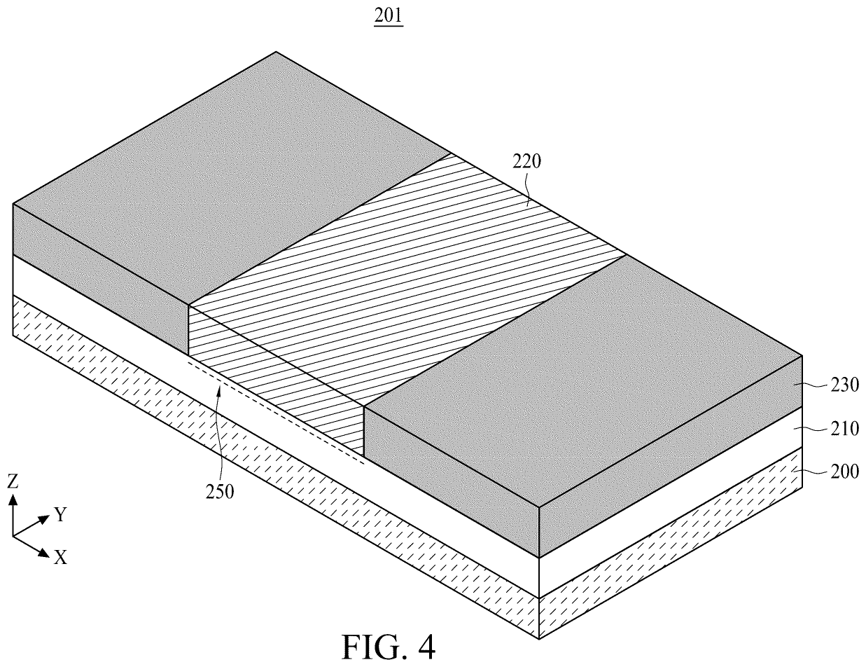

FIG. 4 is a schematic perspective view of a stacked structure 201 that includes portions of the substrate 200, the first semiconductor layer 210, the second semiconductor layer 220, and the isolation feature 230 of the resistive element 20, in accordance with some embodiments of the present disclosure. Referring to FIG. 4, the substrate 200 is a semiconductor substrate. In some embodiments, the semiconductor substrate 200 is made of, for example, silicon, or a compound semiconductor, such as silicon carbide.

In some embodiments, the first semiconductor layer 210 and the second semiconductor layer 220 may have different lattice constants. The lattice constant is referred to as a distance between unit cells (such as atoms) in a crystal lattice. The lattice constant plays a crucial role in defining the physical and chemical properties of a material. In some embodiments, the lattice constant affects the strength, thermal and electrical conductivity, and optical properties of a material. For example, changes in lattice constant may lead to modification in the bandgap of the material. Each of the first semiconductor 210 may have a lattice constant and a bandgap.

In some embodiments, the first semiconductor layer 210 and the second semiconductor layer 220 include semiconductor materials with different bandgaps. For example, the first semiconductor layer 210 may have a bandgap lower than that of the second semiconductor layer 220. For example, the first semiconductor layer 210 includes a binary III-V semiconductor material, such as gallium nitride (GaN), and the second semiconductor layer 220 includes a ternary III-V semiconductor material, such as aluminum gallium nitride (AlGaN). Because the first semiconductor layer 210 and the second semiconductor layer 220 have materials with different bandgaps, a bandgap discontinuity exists between the first and second semiconductor layers 210 and 220, forming a quantum well that confines a two-dimensional electron gas (2DEG) in the first semiconductor layer 210 and near an interface between the first and second semiconductor layers 210 and 220. The 2DEG in the quantum well provides high mobility transport of electrons due to the two-dimensional quantum well confinement of the electrons. The 2DEG may have carrier channel 250 is referred to as a two-dimensional electron gas (2DEG) channel, which is schematically illustrated. In some embodiments, the 2DEG channel is generated naturally in the first semiconductor layer 210 and near an interface between the first and second semiconductor layers 210 and 220.

In some embodiments, the first semiconductor layer 210 is made of GaN, and the second semiconductor layer 220, which overlies the first semiconductor layer 210, may be made of indium aluminum gallium nitride (InAlGaN), indium aluminum nitride (InAlN), aluminum nitride (AlN), aluminum indium nitride (AlInN), or the like. In other embodiments, the first semiconductor layer 210 is made of gallium arsenide (GaAs), and the second semiconductor layer 220, which overlies the first semiconductor layer 210, is made of aluminum gallium arsenide (AlGaAs), indium gallium phosphide (InGaP), indium gallium arsenide (InGaAs), or the like. In some embodiments, the resistive element 20 includes the first semiconductor layer 210 made of indium gallium arsenide (InGaAs) underlying the second semiconductor layer 220 made of aluminum gallium arsenide (AlGaAs), indium aluminum arsenide (InAlAs), or the like. The resistive element 20 may include the second semiconductor layer 220 made of indium arsenide (InAs) stacked on the first semiconductor layer 210 made of aluminum antimonide (AlSb). The resistive element 20 may include the second semiconductor layer 220 made of indium gallium arsenide (InGaAs) stacked on the first semiconductor layer 210 made of indium aluminum arsenide (InAlAs). The resistive element 20 may include the second semiconductor layer 220 made of cadmium tellurium (CdTe) stacked on the first semiconductor layer 210 made of lead telluride (PbTe).

In some embodiments, the second semiconductor layer 220 and the isolation feature 230 include substantially a same material, but have different doping concentrations. For example, the second semiconductor layer 220 is not doped with additional n-type dopant and p-type dopant, while the isolation feature 230 is doped with appropriate dopant impurities. Accordingly, the n-type and p-type dopant concentration in the second semiconductor layer 220 may be equal to or close to zero, while the isolation feature 230 has a doping concentration greater than that of the second semiconductor layer 220. The isolation feature 230 may be, for example, a p-type or n-type doped binary III-V semiconductor layer.

Referring again to FIGS. 2 and 3, in some embodiments, electrical properties of the resistive element 20 are associated with a material composition of the metal layer 240. In an example, a work function value of the metal layer 240 may be used to tune a temperature coefficient of resistance of the resistive element 20. In another example, the work function value of the metal layer 240 may be used to define a zero temperature coefficient voltage (also referred to as a threshold voltage) Vt of the resistive element 20.

The stacked structure 201 shown in FIG. 4 may have a positive temperature coefficient (PTC) of resistance, i.e., may exhibit an increasing resistance with increasing temperature, under a zero-bias condition. In some embodiments, the resistive element 20 (shown in FIG. 3) that includes the metal layer 240 having a work function value greater than about 2.0 eV and less than about 4.3 eV may have a negative temperature coefficient (NTC) of resistance under the zero-bias condition. The resistive element 20 having the negative temperature coefficient of resistance exhibits a decreasing resistance with increasing temperature, and thus has a temperature-dependent characteristic completely opposite to that of the stacked structure 201. Thus, the resistive element 20 including 2DEG can have a wide range of applications in the electronics field.

In some embodiments, the resistive element 20 that includes the metal layer 240 having a work function value equal to or greater than about 4.3 eV may have a positive temperature coefficient (PTC) of resistance under the zero-bias condition. The resistive element 20 having the positive temperature coefficient of resistance may be achieved when the metal layer 240 has the work function between about 4.3 eV and about 6.5 eV. The stacked structure 201 and the resistive element 20 including the metal layer 240 may have different positive temperature coefficients of resistance. In an example, the resistive element 20 may have a greater positive temperature coefficient of resistance than the stacked structure 201; thus, a variation of the effective resistance of the resistive element 20 is greater than that of the stacked structure 201 when the temperature changes, providing a viable solution for circuits that has high sensitivity to varying temperatures. In another example, the resistive element 20 may have a smaller positive temperature coefficient of resistance than the stacked structure 201; thus, a variation of the effective resistance of the resistive element 20 is less than that of the stacked structure 201 when the temperature changes, providing a viable solution for circuits that has high stability under varying temperatures.

Suitable examples of the metal layer 240 included in the resistive element 20 having the negative temperature coefficient of resistance may include cesium (Cs), sodium (Na), potassium (K), calcium (Ca), uranium (U), magnesium (Mg), cadmium (Cd), aluminum (Al), lead (Pb), silver (Ag), other suitable materials having a work function value greater than about 2 eV and less than about 4.3 eV, or any combination thereof. Suitable examples of the metal layer 240 included in the resistive element 20 having the positive temperature coefficient of resistance may include titanium nitride (TiN), niobium (Nb), zinc (Zn), iron (Fe), mercury (Hg), copper (Cu), carbon (C), beryllium (Be), cobalt (Co), nickel (Ni), gold (Au), selenium (Se), platinum (Pt), other suitable materials having a work function value between about 4.3 eV and about 6.5 eV, or any combination thereof.

A bias voltage V_{BIAS} may be applied to the metal layer 240 of the resistive element 20. The bias voltage V_{BIAS} is used to further tune the temperature coefficient of resistance of the resistive element 20. In a condition where the bias voltage V_{BIAS} is equal to the threshold voltage Vt of the resistive element 20, the resistive element 20 may have a temperature coefficient of resistance equal to zero (i.e., zero temperature of resistance). In such condition, the resistance of the resistive element 20 hardly changes at all with variations in temperature. In a condition where the bias voltage V_{BIAS} is greater than the threshold voltage Vt of the resistive element 20, the resistive element 20 may have a positive temperature coefficient of resistance. On the other hand, the resistive element 20 may have a negative temperature coefficient of resistance when the bias voltage V_{BIAS} is less than the threshold voltage Vt of the resistive element 20. Thus, the temperature-dependent characteristic of the resistive element 20 may be adjusted by user according to different operation requirements.

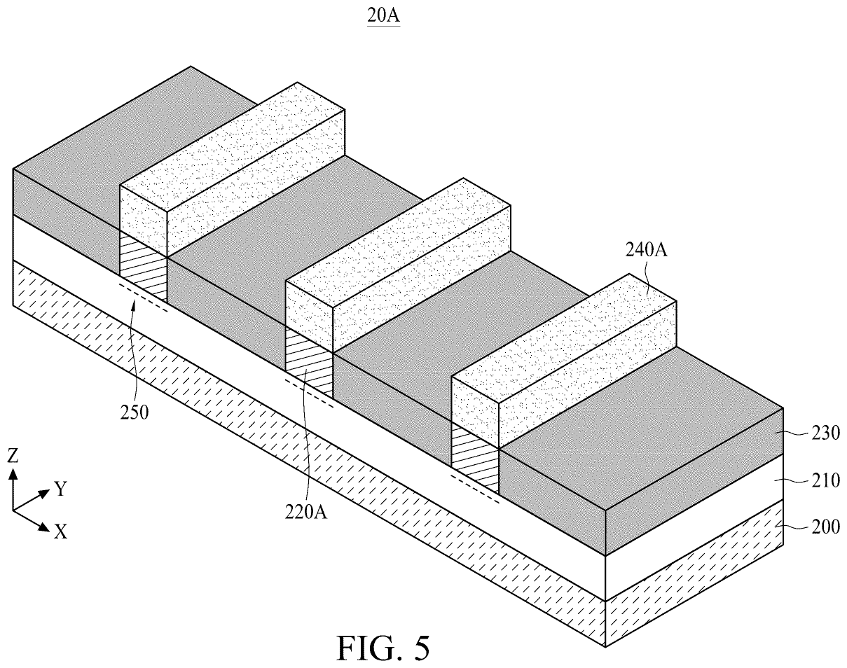

FIG. 5 is a schematic perspective view of a resistive element 20A, in accordance with some embodiments of the present disclosure. The resistive element 20A is similar to the resistive element 20 discussed above, except that the second semiconductor layer 220 and the metal layer 240 are replaced by a second semiconductor layer 220A and a metal layer 240A, respectively. Referring to FIG. 5, the second semiconductor layer 220A and the metal layer 240A may have a straight pattern from a top-view perspective. In some embodiments, the metal layer 240A is stacked on and aligned with the second semiconductor layer 220A.

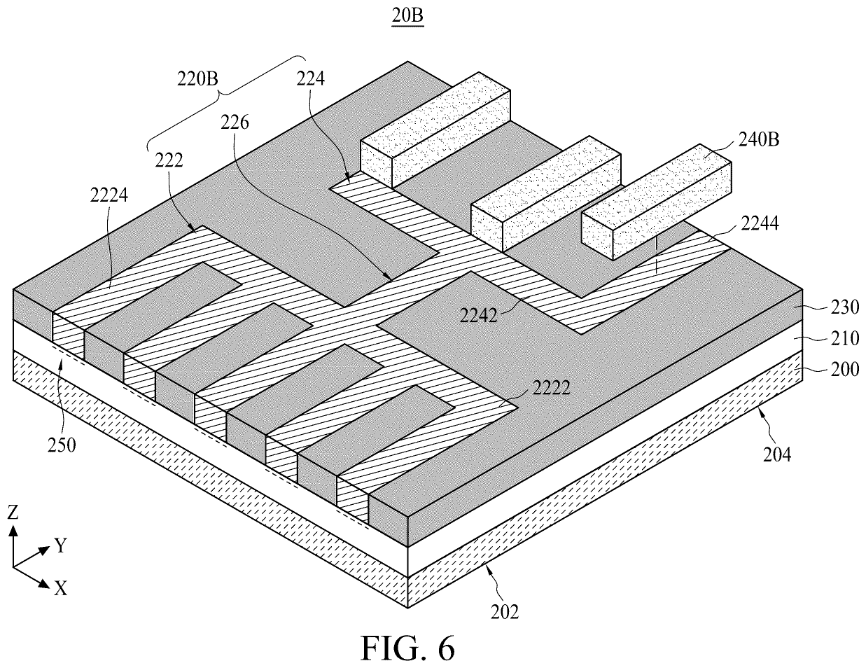

FIG. 6 is a schematic perspective view of a resistive element 20B, in accordance with some embodiments of the present disclosure. The resistive element 20B is similar to the resistive element 20 discussed above, except that the second semiconductor layer 220 and the metal layer 240 are replaced by a second semiconductor layer 220B and a metal layer 240B, respectively. Referring to FIG. 6, in some embodiments, the second semiconductor layer 220B includes a first patterned structure 222, a second patterned structure 224, and an interconnect member 226 connecting the first patterned structure 222 to the second patterned structure 224. As shown in FIG. 6, the first patterned structure 222 has a first comb-shaped pattern, and the second patterned structure 224 has a second comb-shaped pattern; thus, the first patterned structure 222 and the second patterned structure 224 may be referred to hereinafter as a first comb-shaped structure and a second comb-shaped structure, respectively.

In some embodiments, the first comb-shaped structure 222 includes a base 2222 and a plurality of fingers 2224 physically connected to the base 2222. The fingers 2224 are parallel to and spaced apart from each other. A 2DEG channel 250 may be created in a region of the first semiconductor layer 210 under the base 2222 and the fingers 2224; thus, the first comb-shaped structure 222 including five fingers 2224 may be regarded as five resistors electrically connected in parallel. The second comb-shaped structure 224 includes a base 2242 and a plurality of fingers 2244 physically connected to the base 2242. The fingers 2244 are parallel to and spaced apart from each other. The interconnect member 226 connects the base 2222 of the first comb-shaped structure 222 to the base 2242 of the second comb-shaped structure 224. In some embodiments, a number of the fingers 2224 included in the first comb-shaped structure 222 may be different from a number of the fingers 2244 included in the second comb-shaped structure 224. In some embodiments, widths of the fingers 2224 and the widths of the fingers 2244 may be the same, but the disclosure is not limited thereto. In some embodiments, lengths of the fingers 2224 and the lengths of the fingers 2244 may be the same, but the disclosure is not limited thereto. In some embodiments, an extending direction of the fingers 2224 and an extending direction of the fingers 2244 may be the same, but the disclosure is not limited thereto. A 2DEG channel 250 may be created in a region of the first semiconductor layer 210 under the base 2242 and the fingers 2244; thus, the second comb-shaped structure 224 including three fingers 2244 may be regarded as three resistors electrically connected in parallel.

A first portion of the resistive element 20B including a first stacked structure containing the first semiconductor layer 210, the first comb-shaped structure 222 and the interconnect member 226 may be referred to a first sub-resistive element 202. The first comb-shaped structure 222 and the interconnect member 226 are not covered by the metal layer 240B, so that the first stacked structure may have a positive temperature coefficient of resistance. A second portion of the resistive element 20B including a second stacked structure containing the first semiconductor layer 210, the second comb-shaped structure 224, and the metal layer 240B may be referred to a second sub-resistive element 204. In some embodiments, the metal layer 240B is aligned with the fingers 2244 of the second comb-shaped structure 224. A temperature coefficient of resistance nearly equal to zero may be achieved by tuning the second sub-resistive element 204 to have a negative temperature coefficient of resistance equal to a positive temperature coefficient of the first sub-resistive element 202. In some embodiments, the second stacked structure may have the negative temperature coefficient of resistance when the metal layer 240B includes the material having the work function value between about 4.3 CV and about 6.5 eV. In alternative embodiments, the second stacked structure may have the negative temperature coefficient of resistance when a bias voltage V_{BIAS} applied to the metal layer 240B is less a threshold voltage Vt of the resistive element 20.

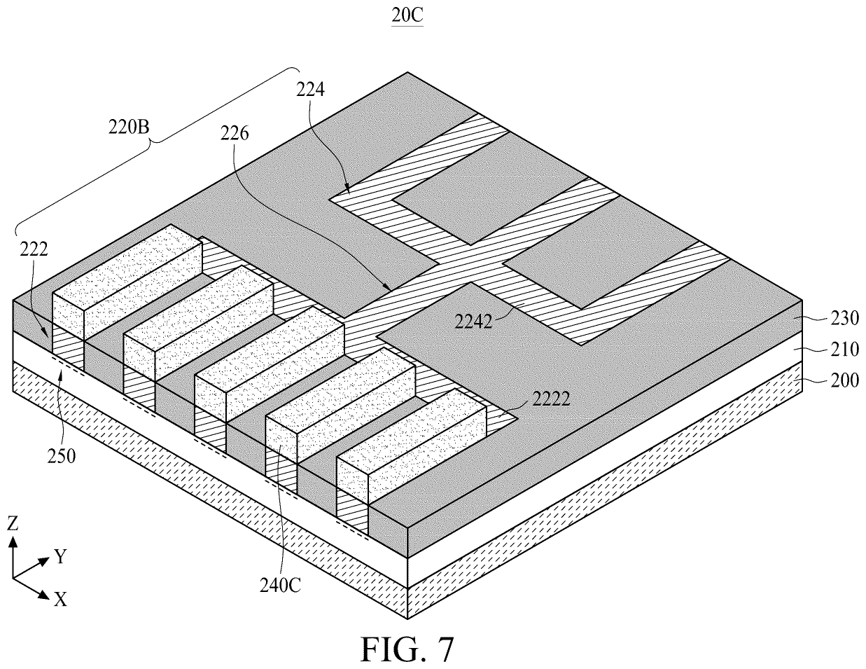

FIG. 7 is a schematic perspective view of a resistive element 20C, in accordance with some embodiments of the present disclosure. The resistive element 20C is similar to the resistive element 20B discussed above, except that the metal layer 240B is replaced by a metal layer 240C. Referring to FIG. 7, in some embodiments, the metal layer 240C is stacked on and aligned with the first comb-shaped structure 222.

A first portion of the resistive element 20C includes a first stacked structure containing the first semiconductor layer 210, the first comb-shaped structure 222, and the metal layer 240C. A second portion of the resistive element 20C includes a second stacked structure containing the first semiconductor layer 210, the second comb-shaped structure 224, and the interconnect member 226. The second comb-shaped structure 224 and the interconnect member 226 are exposed though the metal layer 240C, so that the second stacked structure may have a positive temperature coefficient of resistance. The resistive element 20C may have a temperature coefficient of resistance of nearly zero may be achieved by tuning the first stacked structure to have a negative temperature coefficient of resistance. In some embodiments, the first stacked structure may have the negative temperature coefficient of resistance when the metal layer 240C includes the material having the work function value between about 4.3 eV and about 6.5 eV. In alternative embodiments, the first stacked structure may have the negative temperature coefficient of resistance when a bias voltage V_{BIAS} applied to the metal layer 240C is less a threshold voltage Vt of the resistive element 20.

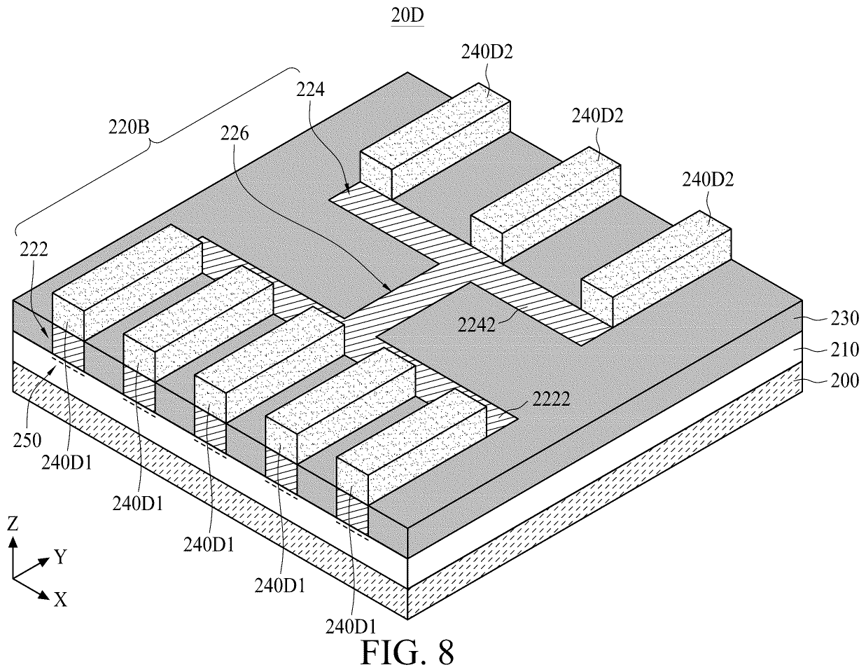

FIG. 8 is a schematic perspective view of a resistive element 20D, in accordance with some embodiments of the present disclosure. The resistive element 20D is similar to the resistive element 20B discussed above, except that the metal layer 240B is replaced by a metal layer 240D1 and a metal layer 240D2. Referring to FIG. 8, in some embodiments, the metal layer 240D1 is stacked on and aligned with the first comb-shaped structure 222, and the metal layer 240D2 is stacked on and aligned with the second comb-shaped structure 224. A material of the metal layer 240D1 may be same as or different from a material of the metal layer 240D2.

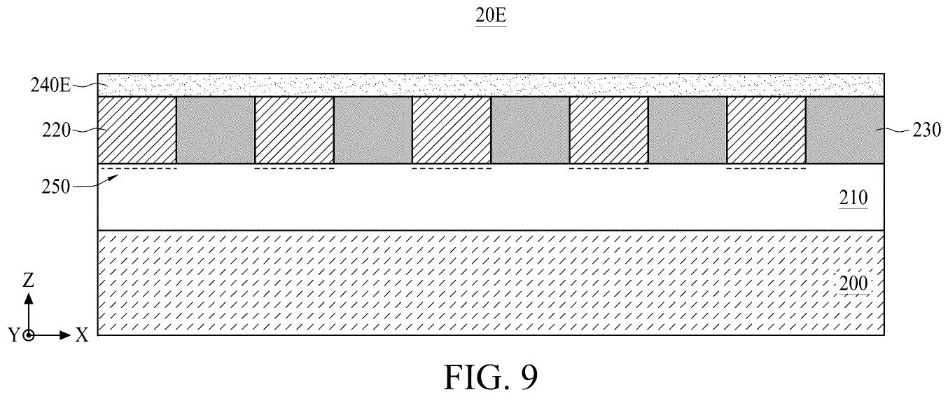

FIG. 9 is a schematic perspective view of a resistive element 20E, in accordance with some embodiments of the present disclosure. The resistive element 20E is similar to the resistive element 20A discussed above, except that the metal layer 240A is replaced by a metal layer 240E. Referring to FIG. 9, in some embodiments, the metal layer 240E is stacked on the second semiconductor layer 220 and the isolation feature 230. The metal layer 240E may fully cover the second semiconductor layer 220 and the isolation feature 230 to simplify process steps and reduce process time. The metal layer 240E may include material having a work function value between about 2 eV and about 6.5 eV for tuning a temperature coefficient of resistance of the resistive element 20E.

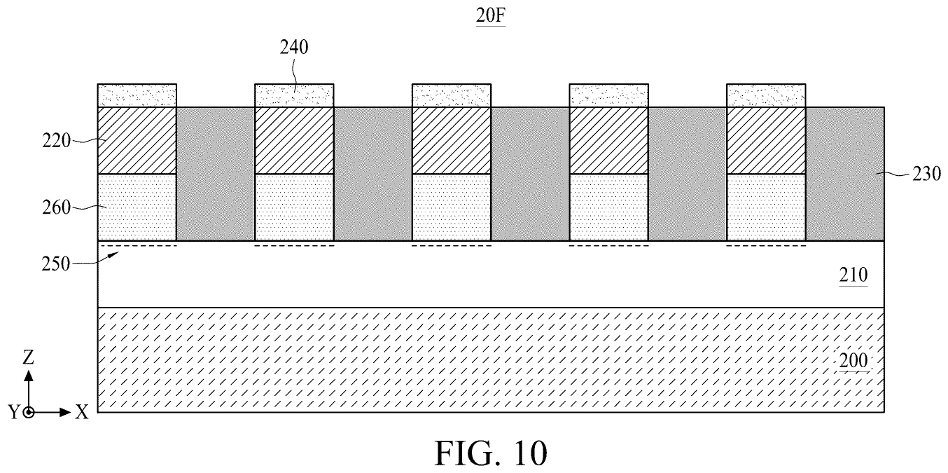

FIG. 10 is a schematic cross-sectional view of a resistive element 20F, in accordance with some embodiments of the present disclosure. Referring to FIG. 10, in some embodiments, the resistive element 20F, has a substrate 200, a first semiconductor layer 210, a second semiconductor layer 220, an isolation feature 230, a metal layer 240, and a third semiconductor layer 260. The first semiconductor layer 210 is disposed on the substrate 200. The third semiconductor layer 260 may be disposed on the first semiconductor layer 210. The second semiconductor layer 220 is stacked on the third semiconductor layer 260.

The second semiconductor layer 220 and the third semiconductor layer 260 are laterally surrounded by the isolation feature 230. The layer 240 is stacked on and aligned to the second semiconductor layer 220. In some embodiments, the first semiconductor layer 210 is made of GaN, and the second semiconductor layer 220 is made of AlGaN. The third semiconductor layer 260, interposed between the first and second semiconductor layers 210 and 220, includes a third semiconductor material having a bandgap higher than that of the first semiconductor layer 210. In some embodiments, the third semiconductor layer 260 is made of aluminum nitride (AlN) or InAlN. The isolation feature 230 may be an amorphous III-V compound layer and a dielectric layer.

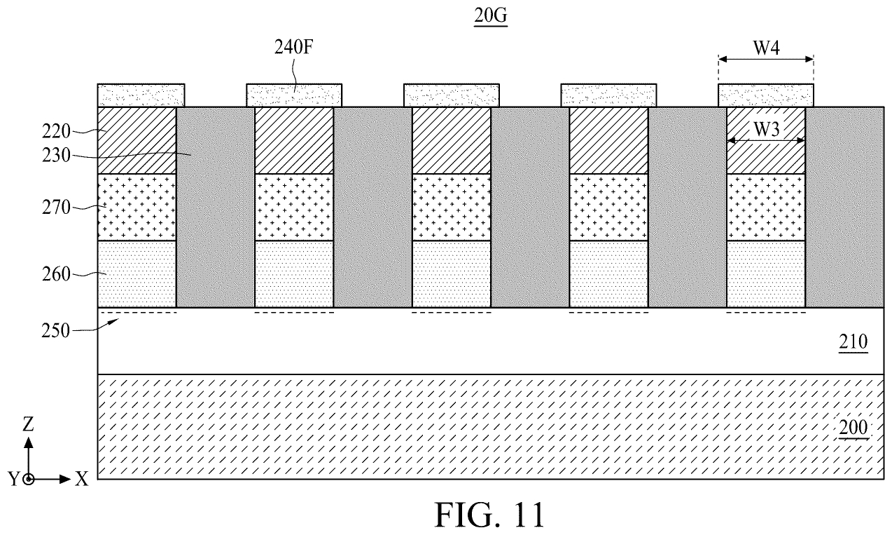

In some embodiments, a resistive element 20G, as shown in FIG. 11, has a substrate 200, a first semiconductor layer 210, a second semiconductor layer 220, an isolation feature 230, a metal layer 240G, a third semiconductor layer 260, and a fourth semiconductor layer 270. The first semiconductor layer 210 is disposed on the substrate 200. In some embodiments, the first semiconductor layer 210 is disposed on an entirety of an upper surface of the substrate 200. The third semiconductor layer 260 and the fourth semiconductor layer 270 are sequentially disposed on the first semiconductor layer 210. The second semiconductor layer 220 is stacked on the fourth semiconductor layer 270. The isolation feature 230 is disposed on the first semiconductor layer 210, and the second semiconductor layer 220, the third semiconductor layer 260, and the fourth semiconductor layer 270 are laterally surrounded by the isolation feature 230.

The metal layer 240G is stacked on the second semiconductor layer 220 and may partially overlap the isolation feature 230. From a cross-sectional view, a width W4 of the metal layer 240G may be greater than a width W3 of the second semiconductor layer 220. In some embodiments, the first and fourth semiconductor layers 210 and 270 are made of GaN, the second semiconductor layer 220 is made of AlGaN, and the third semiconductor layer 260 is made of indium gallium nitride (InGaN). The isolation feature 230 may be an amorphous III-V compound layer or a dielectric layer. The metal layer 240F may include material having a work function value between about 2 eV and about 6.5 eV for tuning a temperature coefficient of resistance of the resistive element 20G.

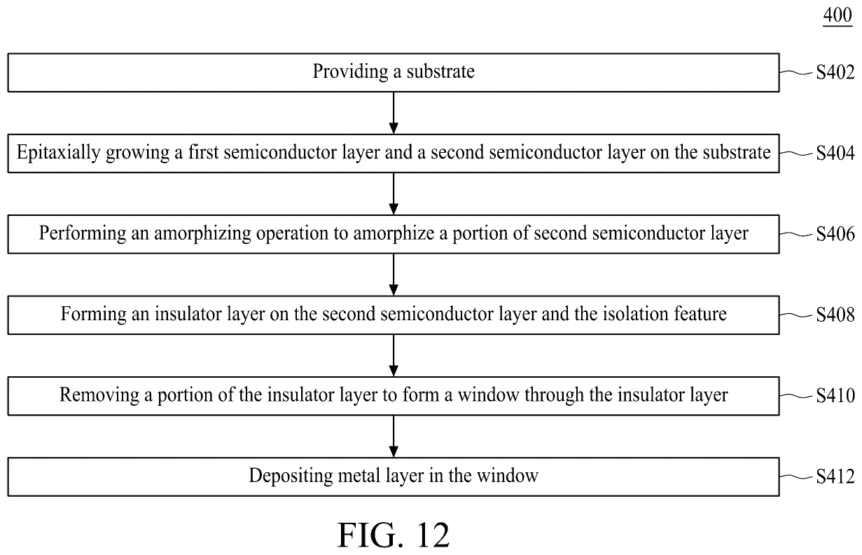

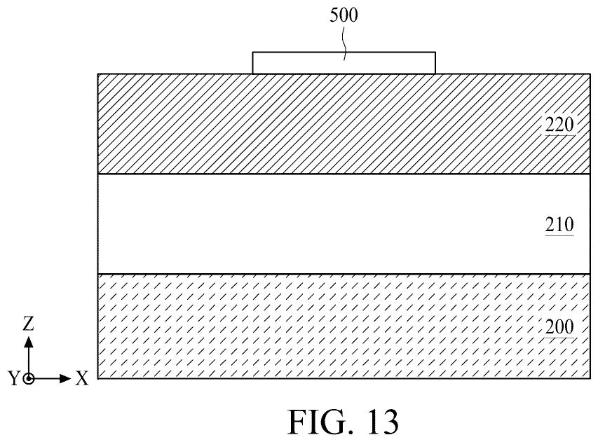

FIG. 12 is a flowchart of a method 400 of manufacturing a resistive element 20, in accordance with some embodiments of the present disclosure. FIGS. 13 to 17 are cross-sectional views of intermediate stages of the method 400 of manufacturing the resistive element 20, in accordance with some embodiments of the present disclosure. In the following description, the manufacturing stages shown in FIGS. 13 to 17 are discussed with reference to the process steps shown in FIG. 12. It should be understood that additional steps can be provided before, during, and after the steps shown in FIG. 12, and some of the steps described below can be replaced or eliminated, for additional embodiments of the method 400. The order of the steps may be changed.

Referring to FIGS. 12 and 13, a substrate 200 is provided in accordance with step S402. The substrate 200 may be a part of a wafer or a bulk substrate formed of bulk material. In some embodiments, the substrate 200 includes a silicon substrate, a silicon carbide (SiC) substrate, a sapphire substrate, or the like. In some embodiments, the substrate 200 is a silicon substrate. Alternative substrate materials, such as sapphire and silicon carbide, may be used for GaN devices.

Subsequently, a first semiconductor layer 210 and a second semiconductor layer 220 are epitaxially grown on the substrate 200 in accordance with step S404. The first semiconductor layer 210 and the second semiconductor layer 220 are sequentially stacked on the substrate 200. In some embodiments, the first semiconductor layer 210 is made of a material having a first bandgap, and the second semiconductor layer 220 is made of a material having a second bandgap greater than the first bandgap. The first semiconductor layer 210 and the second semiconductor layer 220 together form a heterojunction. For example, the first semiconductor layer 210 includes GaN, and the second semiconductor layer 220 includes AlGaN. Each of the first semiconductor layer 210 and the second semiconductor layer 220 is grown on the substrate 200 using a suitable growth technique. For example, each of the first semiconductor layer 210 and the second semiconductor layer 220 is grown using a metal-organic chemical vapor deposition (MOCVD) operation and a molecular beam epitaxy (MBE) operation.

After the formation of the second semiconductor layer 220, a mask layer 500 is disposed over the second semiconductor layer 220. In some embodiments, one or more portions of the second semiconductor layer 220 are covered by the mask layer 500 to define a desired pattern of the resistive element 20.

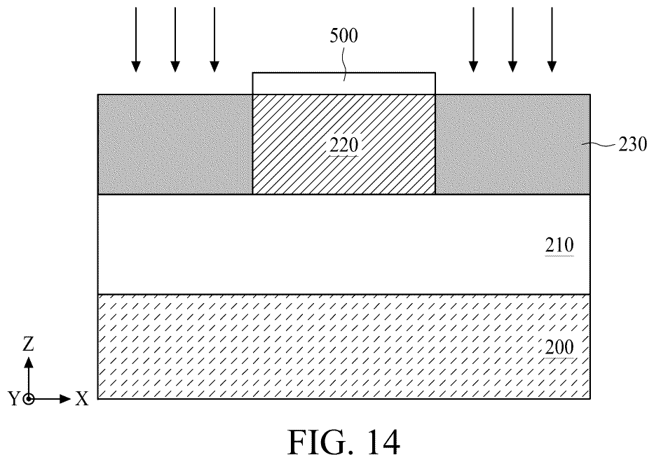

Referring to FIG. 14, an amorphizing operation is performed to amorphize at least a portion of the second semiconductor layer 220 not protected by the mask layer 500 in accordance with step S406. Accordingly, at least an isolation feature 230 is formed, wherein the isolation feature 230 is an amorphized region of the second semiconductor layer 220. In some embodiments, the amorphizing operation includes performing an implantation process to introduce impurities into the portion of the second semiconductor layer 220. After the amorphizing operation, the amphorized region may have a disoriented crystal structure. The impurities may include nitrogen, argon, carbon, fluorine or a combination thereof. In some embodiments, the second semiconductor layer 220 and the isolation feature 230 have substantially a same composition. In some embodiments, the implantation operation is performed, for example but not limited thereto, at an energy of about 1 KeV to 600 KeV and a dose of about 10¹² atom/cm³ to 10¹⁶ atom/cm³. After the amorphizing operation, the mask layer 500 is removed using suitable operations.

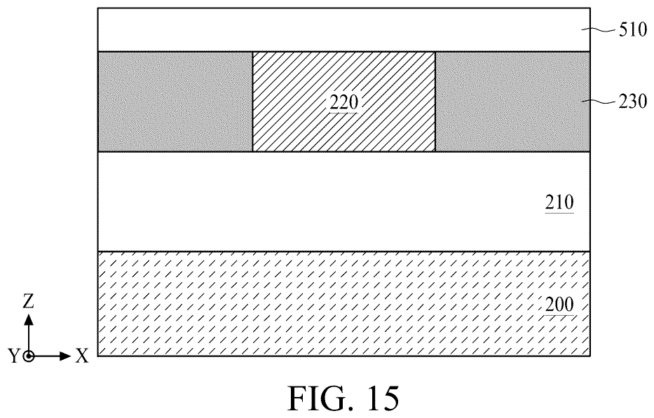

Referring to FIG. 15, an insulator layer 510 is formed on the second semiconductor layer 220 and the isolation feature 230 in accordance with step S408 in FIG. 12. In some embodiments, the insulator layer 510 includes an oxide (such as silicon oxide), a nitride (such as silicon nitride), or an oxynitride (such as silicon oxynitride). In some embodiments, the insulator layer 510 completely covers upper surfaces of the second semiconductor layer 220 and the isolation feature 230. The insulator layer 510 including the oxide may be formed using a thermal oxidization operation or a deposition operation such as chemical vapor deposition (CVD). The insulator layer 510 including the nitride or the oxynitride may be deposited on the second semiconductor layer 220 and the isolation feature 230 by low-pressure chemical vapor deposition (LPCVD) or plasma-enhanced chemical vapor deposition (PECVD).

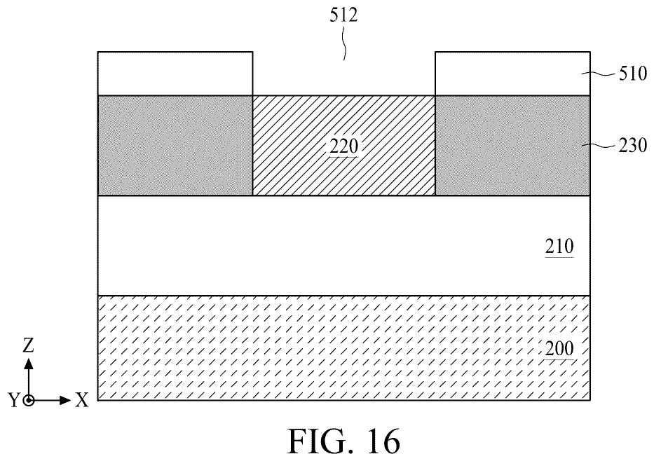

Referring to FIG. 16, a portion of the insulator layer 510 is removed in accordance with step S410 in FIG. 12. Accordingly, a window 512 is formed through the insulator layer 510 to expose a portion of the second semiconductor layer 220. In some embodiments, the insulator layer 510 is patterned using a lithography and an etching operation to make the window 512.

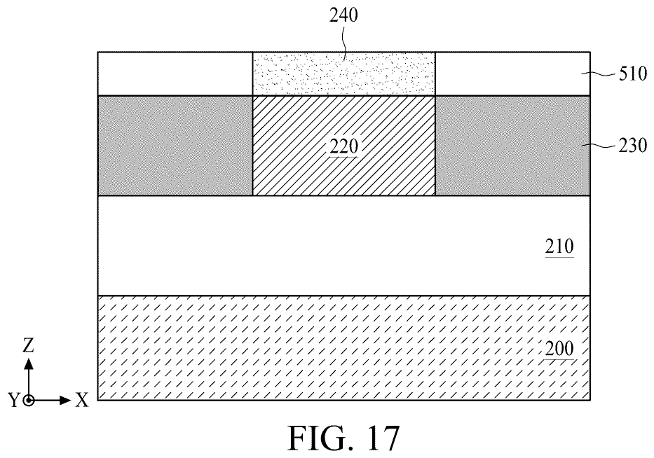

Referring to FIG. 17, a metal layer 240 is deposited in the window 512 in accordance with step S412 in FIG. 12. Consequently, the resistive element 20 is completely formed. The metal layer 240 is deposited until the window 512 is entirely filled. The metal layer 240 may be formed by CVD, atomic layer deposition (ALD), and/or another suitable process. In some embodiments, the metal layer 240 can be planarized, such as by a chemical mechanical polishing (CMP) operation, to have a planar top surface. The insulator layer 510 may be removed from the second semiconductor layer 220 and the isolation feature 230 after the metal layer 240 is completely formed.

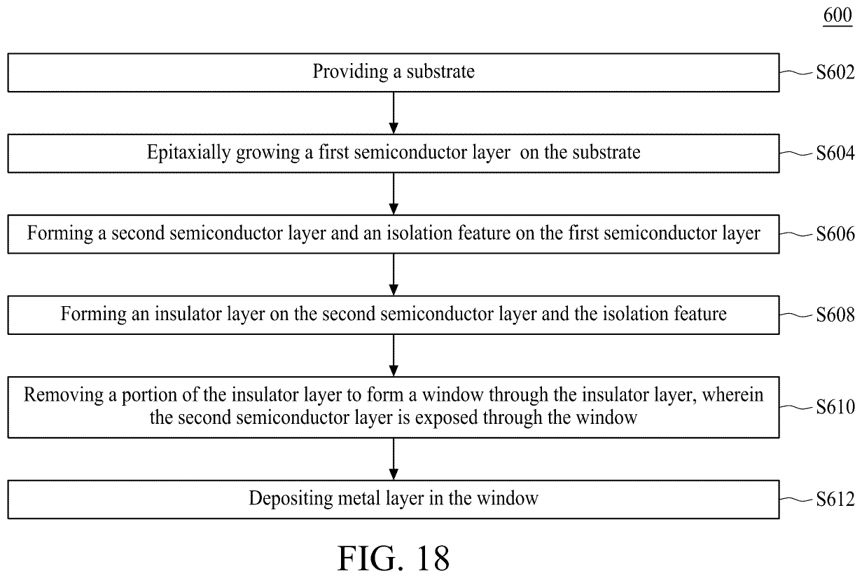

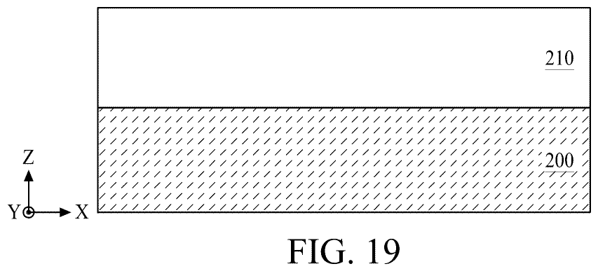

FIG. 18 is a flowchart of a method 600 of manufacturing a resistive element 20, in accordance with some embodiments of the present disclosure. FIGS. 19 to 23 are cross-sectional views of intermediate stages of the method 600 of manufacturing the resistive element 20, in accordance with some embodiments of the present disclosure. In the following description, the manufacturing stages shown in FIGS. 19 to 23 are discussed with reference to the process steps shown in FIG. 18. It should be understood that additional steps can be provided before, during, and after the steps shown in FIG. 18, and some of the steps described below can be replaced or eliminated, for additional embodiments of the method 600. The order of the steps may be changed.

Referring to FIG. 19, a substrate 200 is provided in accordance with step S602 in FIG. 18. The substrate 200 may be a part of a wafer or a bulk substrate formed of bulk material. In some embodiments, the substrate 200 is a silicon substrate. Alternative substrate materials, such as sapphire and silicon carbide, may be used for GaN devices.

Subsequently, a first semiconductor layer 210 is epitaxially grown on the substrate 200 in accordance with step S604 in FIG. 18. In some embodiments, the first semiconductor layer 210 is disposed on an entirety of a top surface of the substrate 200. The first semiconductor layer 210 may include first material having a first bandgap. In some embodiments, the first semiconductor layer 210 includes GaN.

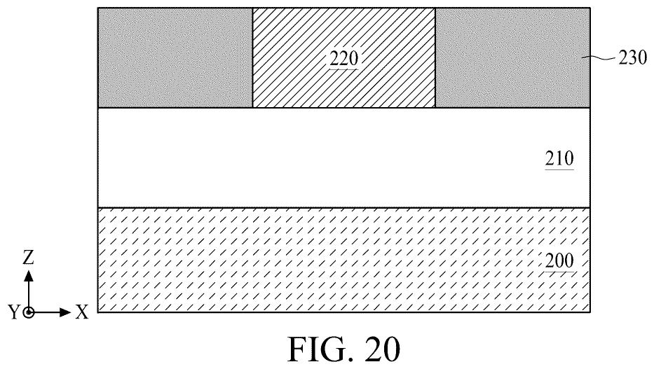

Referring to FIG. 20, a second semiconductor layer 220 and an isolation feature 230 are formed on the first semiconductor layer 210 in accordance with step S606 in FIG. 18. The second semiconductor layer 220 may be laterally surrounded by the isolation feature 230. The second semiconductor layer 220 may be formed prior to the formation of the isolation feature 230. For example, the second semiconductor layer 220 is formed by patterning a second material layer which is blanketly grown on the first semiconductor layer 210. The second semiconductor layer 220 may be formed from a patterned second material layer. The second material layer 220 may be patterned by the use of masking method, lithography operation, etching operation, or combinations thereof, such that a window is formed to expose the a portion of the first semiconductor layer 210. The window in the second semiconductor layer 220 are then filled with a dielectric material to form the isolation feature 230. The second semiconductor layer 220 may be grown on the first semiconductor layer 210 using an MOCVD operation and an MBE operation. The isolation feature 230 may be formed by performing a suitable deposition operation to over-fill the window and a removal operation to remove excess portion of the dielectric material above the upper surface of the second semiconductor layer 220.

The second semiconductor layer 220 may be formed after the formation of the isolation feature 230. For example, the isolation feature 230 is formed on the first semiconductor layer 210 by blanketly depositing a dielectric layer on the first semiconductor layer 210, patterning the dielectric layer to form the isolation feature with at least one window, and filling the window with a second material to thereby form the second semiconductor layer 220 laterally surround by the isolation feature 230.

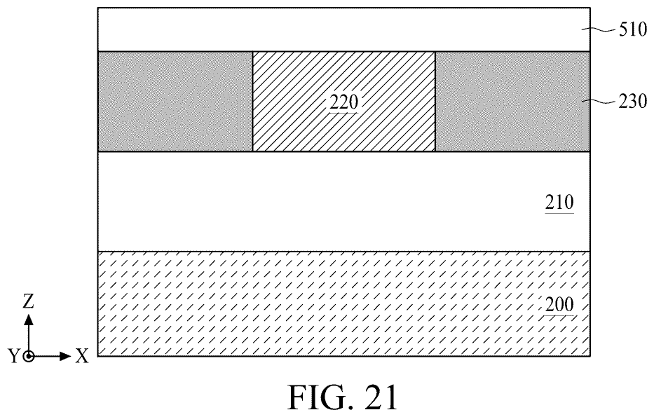

Referring to FIG. 21, an insulator layer 510 is formed on the second semiconductor layer 220 and the isolation feature 230 in accordance with step S608 in FIG. 18. In some embodiments, the insulator layer 510 includes an oxide, a nitride, or an oxynitride. In some embodiments, the insulator layer 510 completely covers upper surfaces of the second semiconductor layer 220 and the isolation feature 230. The insulator layer 510 may be formed using suitable operations.

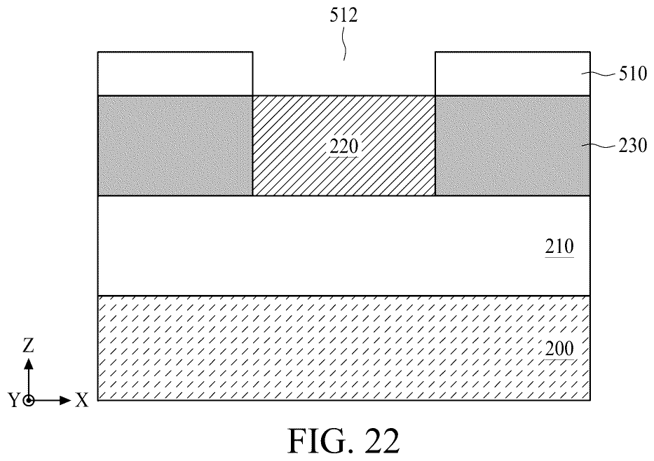

Referring to FIG. 22, a portion of the insulator layer 510 is removed in accordance with step S610 in FIG. 18. Accordingly, a window 512 is formed through the insulator layer 510 to expose a portion of the second semiconductor layer 220. In some embodiments, the insulator layer 510 is patterned using a lithography and an etching operation to make the window 512.

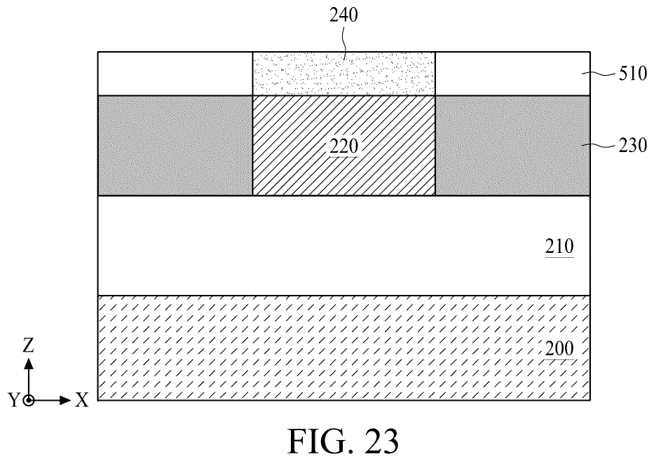

Referring to FIG. 23, a metal layer 240 is deposited in the window 512 in accordance with step S612 in FIG. 12. Consequently, the resistive element 20 is completely formed. The metal layer 240 is deposited until the window 512 is entirely filled. The metal layer 240 may be formed by CVD, atomic layer deposition (ALD), and/or another suitable process. In some embodiments, the metal layer 240 can be planarized, such as by a CMP operation, to have a planar top surface. The insulator layer 510 may be removed from the second semiconductor layer 220 and the isolation feature 230 after the metal layer 240 is completely formed.

In accordance with some embodiments of the present disclosure, a semiconductor structure includes: a first semiconductor layer comprising a first material having a first bandgap; a second semiconductor layer disposed on the first semiconductor layer, wherein the second semiconductor layer comprises a second material having a second bandgap, and the second bandgap is different from the first bandgap; and a metal layer at least partially overlapping the second semiconductor layer, wherein an interface lattice mismatch (carrier channel) is formed between the first semiconductor layer and the second semiconductor layer.

In accordance with some embodiments of the present disclosure, a semiconductor device comprises a first semiconductor layer comprising a first material having a first bandgap; a second semiconductor layer disposed on the first semiconductor layer and comprising a first patterned structure, a second patterned structure, and an interconnect member connecting the first patterned structure and the second patterned structure, wherein the second semiconductor layer comprises a second material having a second bandgap, and the second bandgap is greater than the first bandgap; and a work function metal layer stacked on at least part of the second patterned structure.

In accordance with some embodiments of the present disclosure, a method of forming a semiconductor structure comprises steps of depositing a first semiconductor layer on a substrate; depositing a second semiconductor layer on the first semiconductor layer; performing an amorphizing operation to amorphize at least a portion of the second semiconductor layer to form an isolation feature laterally surrounding the remaining second semiconductor layer; and depositing a metal layer fully overlapping the remaining second semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first semiconductor layer comprising a first material having a first bandgap;
a second semiconductor layer disposed on the first semiconductor layer, wherein the second semiconductor layer comprises a second material having a second bandgap, and the second bandgap is different from the first bandgap; and
a metal layer at least partially overlapping the second semiconductor layer,
wherein an interface lattice mismatch is formed between the first semiconductor layer and the second semiconductor layer.

2. The semiconductor structure of claim 1, further comprising an isolation feature disposed on the first semiconductor layer, wherein the second semiconductor layer is laterally surrounded by the isolation feature.

3. The semiconductor structure of claim 2, wherein the metal layer fully covers the second semiconductor layer and the isolation feature.

4. The semiconductor structure of claim 2, wherein the second semiconductor layer and the isolation feature comprise a same material, but have different doping concentrations.

5. The semiconductor structure of claim 4, wherein a dopant concentration in the second semiconductor layer is equal to or close to zero.

6. The semiconductor structure of claim 2, wherein an upper surface of the second semiconductor layer is flush with an upper surface of the isolation feature.

7. The semiconductor structure of claim 2, further comprising a third semiconductor layer interposed between the first semiconductor layer and the second semiconductor layer, wherein the third semiconductor layer is laterally surrounded by the isolation feature.

8. The semiconductor structure of claim 1, wherein the metal layer is aligned with the second semiconductor layer.

9. The semiconductor structure of claim 1, wherein the semiconductor structure has a threshold voltage and a temperature coefficient of resistance, and the temperature coefficient of resistance is equal to zero when a bias voltage applied to the metal layer is equal to the threshold voltage.

10. The semiconductor structure of claim 1, wherein the semiconductor structure has a positive temperature coefficient of resistance when a bias voltage applied to the metal layer is greater than a threshold voltage of the semiconductor structure.

11. The semiconductor structure of claim 1, wherein the semiconductor structure has a negative temperature coefficient of resistance when a bias voltage applied to the metal layer is less than a threshold voltage of the semiconductor structure.

12. A semiconductor device, comprising:
a first semiconductor layer comprising a first material having a first bandgap;
a second semiconductor layer disposed on the first semiconductor layer and comprising a first patterned structure, a second patterned structure, and an interconnect member connecting the first patterned structure and the second patterned structure, wherein the second semiconductor layer comprises a second material having a second bandgap, and the second bandgap is different from the first bandgap; and
a work function metal layer stacked on at least part of the second patterned structure.

13. The semiconductor device of claim 12, wherein the first semiconductor layer, and the first patterned structure form a first resistive element having a positive temperature coefficient of resistance, and the first semiconductor layer, the second patterned structure, and the work function metal layer collectively function as a second resistive element having a negative temperature coefficient of resistance.

14. The semiconductor device of claim 12, further comprising an isolation feature disposed on the first semiconductor layer, wherein the first patterned structure and the second patterned structure are laterally surrounded by the isolation feature.

15. The semiconductor device of claim 14, wherein the second semiconductor layer and the isolation feature have a same material, but have different doping concentrations.

16. The semiconductor device of claim 12, wherein the work function metal layer is further stacked on the first patterned structure.

17. A method of forming a semiconductor structure, comprising:
depositing a first semiconductor layer on a substrate;
forming a second semiconductor layer on the first semiconductor layer;
forming an isolation feature laterally surrounding the second semiconductor layer; and
depositing a metal layer fully overlapping the at least a part of the second semiconductor layer.

18. The method of claim 17, wherein the deposition of the metal layer comprises:
forming an insulator layer on the second semiconductor layer and the isolation feature;
forming a window in the insulator layer to expose the second semiconductor layer; and
depositing a metal material in the window.

19. The method of claim 18, wherein the insulator layer is formed by oxidizing the second semiconductor layer and the isolation feature.

20. The method of claim 17, wherein the formation of the isolation feature comprises amorphizing at least a portion of the second semiconductor layer.
